(19) United States
(12) Patent Application Publication
(10) Pub. No.: US 2026/0070753 A1
(43) Pub. Date: Mar. 12, 2026

(54) SHEET SUPPLYING APPARATUS AND SUPPLYING METHOD FOR SHEET THEREBY

(71) Applicant: ADDFA CO., LTD., Cheonan-si (KR)

(72) Inventor: Hyungjin PARK, Cheonan-si (KR)

(21) Appl. No.: 19/323,026

(22) Filed: Sep. 9, 2025

(30) Foreign Application Priority Data
Sep. 9, 2024 (KR) 10-2024-0122555
Sep. 8, 2025 (KR) 10-2025-0127634

(51) Int. Cl. B65H 19/10; B65H 16/02; B65H 19/18; B65H 23/185; H04N 23/54; H04N 23/66; H10F 19/80; H10F 71/00

(52) U.S. Cl. CPC B65H 19/105; B65H 16/024; B65H 19/1805; B65H 19/1868; B65H 23/185; H10F 19/804; H10F 71/137; B65H 2301/41354; B65H 2301/4602; B65H 2301/4695; B65H 2402/352; B65H 2403/52; B65H 2553/42; B65H 2555/24; H04N 23/54; H04N 23/66

(57) ABSTRACT

Described herein is a sheet supply apparatus for continuously supplying sheets while splicing the leading edge of the sheet of a standby roll to the trailing end of a sheet being unwound from a working roll by using an auto splicer, the sheet supply apparatus including: a turret unwinder provided with fixation chucks that each fix both ends of a paper tube, and configured to switch the positions of the standby and working rolls; a detector configured to detect the position of one of both axial ends of the standby roll; a corrector configured to be connected to each of the fixation chucks and to correct the position of the standby roll; and a controller configured to align an end of the standby roll so that the end of the standby roll is aligned with the end of the working roll while correcting the position of the standby roll.

### CROSS-REFERENCE TO RELATED APPLICATION

This application claims the benefit of Korean Patent Applications No. 10-2024-0122555 filed on Sep. 9, 2024 and No. 10-2025-0127634 filed on Sep. 8, 2025, which are hereby incorporated by reference herein in their entireties.

### BACKGROUND

### 1. Technical Field

The embodiments disclosed herein relate to a sheet supply apparatus and a sheet supply method using the same, and more particularly, to a sheet supply apparatus and method that may continuously supply sheets while splicing the trailing end of a sheet being unwound from a working roll to the leading end of a sheet wound on a standby roll by using an auto splicer.

### 2. Description of the Related Art

Generally, solar modules are each formed of EVA sheets, solar cells, glass, and a frame in order.

In this case, the EVA (Ethyl Vinyl Acetate) sheets serve to protect the solar cells from external environments, such as moisture infiltration, and are essential for maintaining the typical 20 to 30 year lifespan of solar cells.

More specifically, the EVA sheets are positioned on the front and back surfaces of the solar cells, so that they act as cushioning materials that prevent damage to the solar cells and perform sealing by bonding the front glass and the back sheet to each other.

These EVA sheets need to be precisely manufactured and integrated into the solar modules because they need to ensure performance and maintain adhesive strength regardless of long-term use.

These EVA sheets for solar modules are manufactured continuously and supplied in a rolled form. At a manufacturing site, they are cut to a set size suitable for each solar module and stacked onto the front glass.

To this end, the EVA sheets for solar modules are continuously supplied in a roll-to-roll fashion.

More specifically, when a working roll runs out of a sheet while an EVA sheet is wound on the working roll, unwound, and then cut, EVA sheets are continuously supplied by splicing the trailing edge of a work sheet to the leading edge of a standby sheet.

In this case, conventionally, to continuously splice the sheets, an operator manually applies double-sided tape to the work sheet and then manually moves the standby roll to splice the two sheets together. However, this process has a problem of inefficiency in that work time increases due to manual operation and two sheets are not accurately spliced to each other.

Furthermore, recently, as rolls are automatically supplied by an autonomous mobile robot (AMR) due to unmanned automation, the importance of a method of accurately splicing two sheets has further increased.

Accordingly, recently, sheets are spliced to each other by applying technologies for automatically splicing the sheets of two rolls, such as an auto-splicing device for roll-to-roll feeding equipment disclosed in Korean Patent No. 10-2474343.

The conventional art described above is an auto-splicing technology that, when a sheet being unwound from a first supply roll is depleted, attaches tape to a second supply roll and automatically splices the second supply roll with the first supply roll.

In this case, for auto-splicing, the second supply roll needs to be aligned such that the ends of the sheets of the first and second supply rolls correspond to each other. When the alignment is not achieved, material shifting occurs at a splicing region due to the misalignment of the sheets.

When material shifting occurs as described above, the sheet of the second supply roll is stacked in the state of being shifted by the amount of misalignment during a stacking process after being cut, resulting in a product defect.

Furthermore, the conventional art has a problem in that when the sheet wound on the second supply roll is wound in an inclined state during the process of being wound on the roll and then meanders during an unwinding process, the sheet of the second supply roll is cut in an inclined state, thereby further worsening the defect.

Therefore, there is a demand for technology for overcoming the above-described problems.

Meanwhile, the above-described background technology corresponds to technical information that has been possessed by the present inventor in order to contrive the present invention or that has been acquired in the process of contriving the present invention, and can not necessarily be regarded as known technology that had been known to the public prior to the filing of the present invention.

### SUMMARY

An object of the embodiments disclosed herein is to propose a sheet supply apparatus and method that may splice the leading edge of a sheet wound on a standby roll to the trailing edge of a sheet being unwound from a working roll by using an auto splicer, may detect one of the axial ends of only the standby roll and may align and correct the end of the standby roll so that it corresponds to the end of the working roll.

Another object of the embodiments disclosed herein is to propose a sheet supply apparatus and method that may construct a fixation chuck for fixing the end of a standby roll by using an axially movable mechanical chuck and may adjust the position of the standby roll while accurately moving the mechanical chuck via the configuration of a servomotor.

Another object of the embodiments disclosed herein is to propose a sheet supply apparatus and method that may accurately detect and provide the position of an axial end of a standby roll and may further correct the meandering of a sheet by, after the standby roll has been switched to the position of a working roll, detecting the edge of a sheet being unwound from the working roll and correcting the position of the working roll.

Another object of the embodiments disclosed herein is to propose a sheet supply apparatus and method that may correct the angle of a sheet being unwound from a working roll by moving a turret unwinder via a member that movably supports the bottom of the turret unwinder. Another object of the embodiments disclosed herein is to propose a sheet supply apparatus and method that may allow a paper tube having run out of a sheet to be smoothly separated from a fixation chuck.

As a technical solution for achieving the above-described object, according to one embodiment, there is provided a sheet supply apparatus for continuously supplying sheets while splicing the leading edge of the sheet of a standby roll to the trailing end of a sheet being unwound from a working roll by using an auto splicer, the sheet supply apparatus including: a turret unwinder provided with fixation chucks that each fix both ends of a paper tube forming the central axis of each of the working and standby rolls so that the working and standby rolls can be rotatably mounted thereon to allow the unwinding of the sheets, and configured to switch the positions of the standby and working rolls to each other when the working roll runs out of the sheet; a detector configured to detect the position of one of both axial ends of the standby roll mounted on the turret unwinder; a corrector configured to be connected to each of the fixation chucks constituting parts of the turret unwinder and to correct the position of the standby roll by moving the fixation chuck in the axial direction; and a controller configured to align an end of the standby roll so that the end of the standby roll is aligned with the end of the working roll while correcting the position of the standby roll by controlling the operation of the corrector based on information about the position of the standby roll detected by the detector.

Furthermore, as a technical solution for achieving the above-described object, according to one embodiment, there is provided a sheet supply method, the sheet supply method being performed by a sheet supply apparatus for continuously supplying sheets while splicing the leading edge of the sheet of a standby roll to the trailing end of a sheet being unwound from a working roll by using an auto splicer, the sheet supply method including: loading and mounting the standby roll onto a turret unwinder mounted with the working roll; detecting the position of one of both axial ends of the standby roll mounted on the turret unwinder; and correcting the position of the standby roll while moving the standby roll axially so that an end of the standby roll is aligned with an end of the working roll based on information about the position of the standby roll detected in the detecting.

### BRIEF DESCRIPTION OF THE DRAWINGS

FIG. 1 is a perspective view showing the configuration of a sheet supply apparatus according to one embodiment;

FIG. 2 is a perspective view showing the turret unwinder of a sheet supply apparatus according to one embodiment;

FIG. 3 is a block diagram showing a sheet supply apparatus according to one embodiment;

FIG. 4 is a diagram showing the configuration of the detector of a sheet supply apparatus according to one embodiment;

FIG. 5 is a diagram showing the configuration of the corrector of a sheet supply apparatus according to one embodiment;

FIG. 6 is a block diagram showing the controller of a sheet supply apparatus according to one embodiment;

FIG. 7 is a flowchart showing a sheet supply method according to one embodiment;

FIG. 8 is a diagram showing the configurations of rolls;

FIG. 9 is a diagram illustrating the movement of a standby roll by the corrector;

FIG. 10 is a diagram illustrating the movement of a working roll by the corrector;

FIG. 11 is a diagram showing the configuration of the paper tube clamp of a sheet supply apparatus according to one embodiment; and

FIG. 12 is a diagram showing the operating state of the paper tube clamp.

### DETAILED DESCRIPTION

Various embodiments will be described in detail below with reference to the accompanying drawings. The following embodiments may be modified to various different forms and then practiced. In order to more clearly illustrate features of the embodiments, detailed descriptions of items that are well known to those having ordinary skill in the art to which the following embodiments pertain will be omitted. Furthermore, in the drawings, portions unrelated to descriptions of the embodiments will be omitted. Throughout the specification, like reference symbols will be assigned to like portions.

Throughout the specification, when one component is described as being “connected” to another component, this includes not only a case where the one component is ‘directly connected’ to the other component but also a case where the one component is ‘connected to the other component with a third component arranged therebetween.’ Furthermore, when one portion is described as “including” one component, this does not mean that the portion does not exclude another component but means that the portion may further include another component, unless explicitly described to the contrary.

Embodiments will be described in detail below with reference to the accompanying drawings.

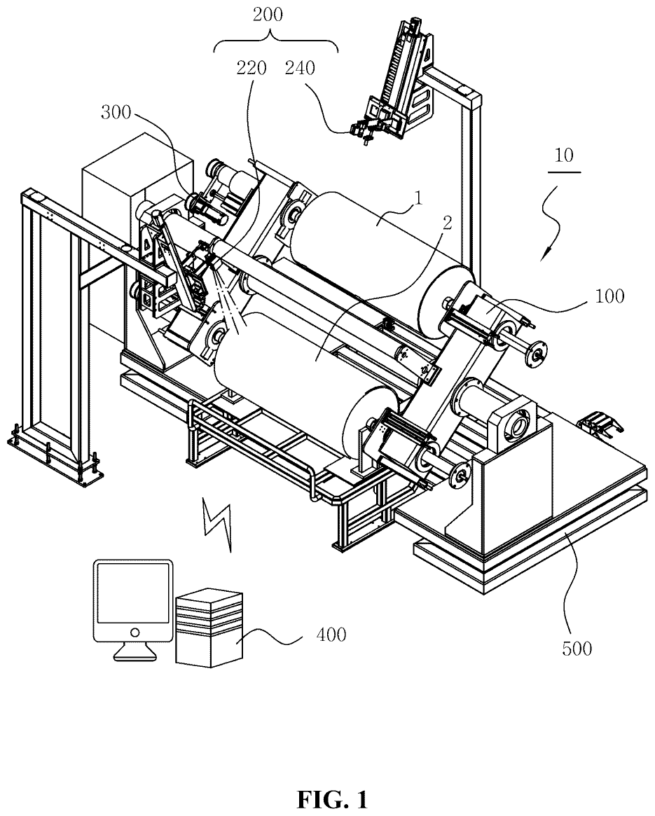

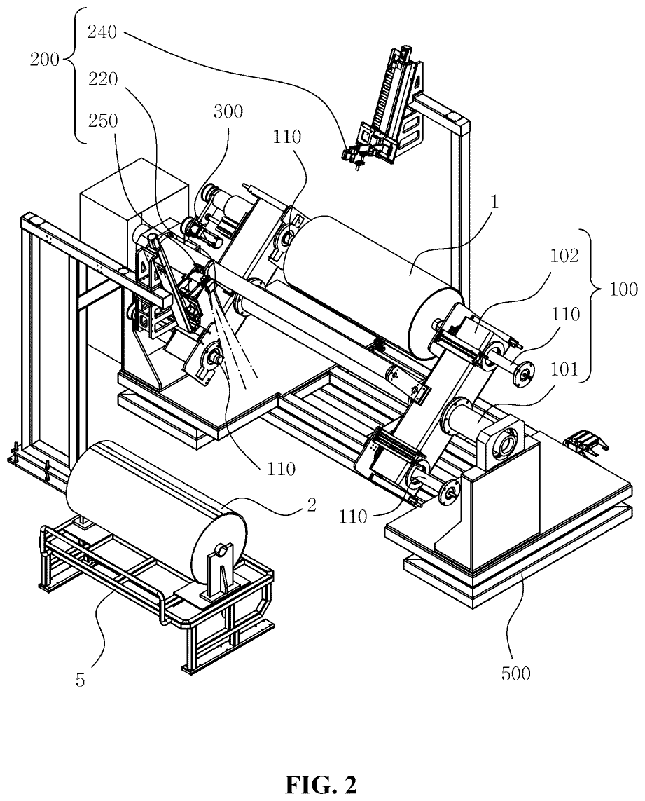

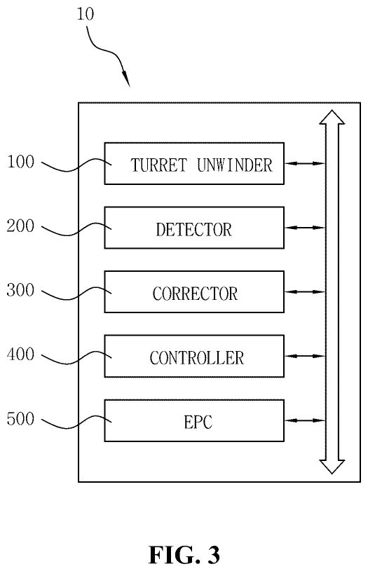

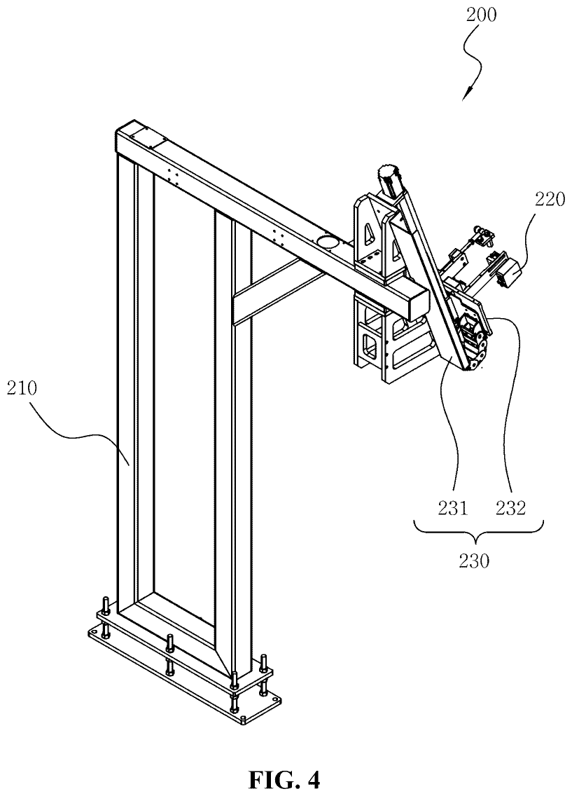

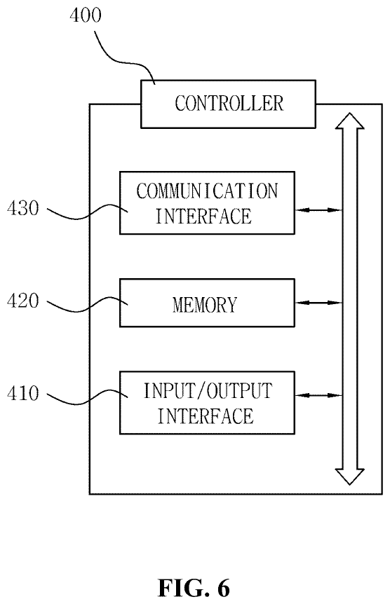

FIG. 1 is a perspective view showing the configuration of a sheet supply apparatus according to one embodiment, FIG. 2 is a perspective view showing the turret unwinder of a sheet supply apparatus according to one embodiment, and FIG. 3 is a block diagram showing a sheet supply apparatus according to one embodiment. Furthermore, FIG. 4 is a diagram showing the configuration of the detector of a sheet supply apparatus according to one embodiment, FIG. 4 is a diagram showing the configuration of the corrector of a sheet supply apparatus according to one embodiment, and FIG. 6 is a block diagram showing the configuration of a controller.

A sheet supply apparatus 10 according to one embodiment is intended to splice sheets to each other in a roll-to-roll fashion and continuously supply them. As shown in FIG. 1, the sheet supply apparatus 10 is an apparatus that splices the leading edge of a sheet wound on a standby roll 2 to the trailing edge of a sheet being unwound from a working roll 1 by using an auto splicer (not shown) and continuously supplies the sheets.

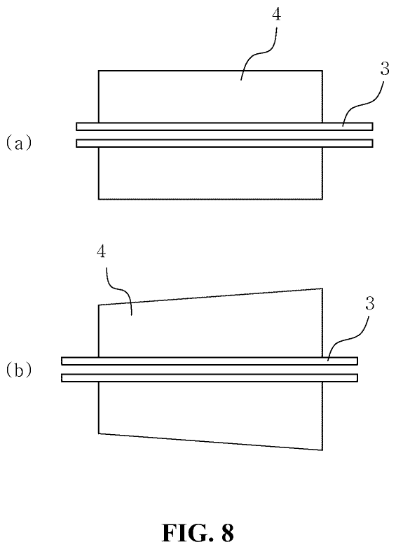

In this case, the working and standby rolls 1 and 2 may be formed of sheets 4 that are each supplied in the state of being wound around a paper tube 3 constituting the central axis, as shown in FIG. 8. In this case, in each of the working roll 1 and standby roll 2, the left and right protrusion lengths of the paper tube 3 may become different during the process of winding the sheet 4, as shown in FIG. 8(a), and the sheet 4 may be wound in an inclined state, as shown in FIG. 8(b).

Meanwhile, the sheets 4 constituting the working and standby rolls 1 and 2 may be formed of, for example, ethyl vinyl acetate (EVA) sheets used in solar modules. Furthermore, any type of sheets spliced to each other in a roll-to-roll fashion may be applied as the sheets 4.

More specifically, the sheet supply apparatus 10 according to one embodiment may be configured to include a turret unwinder 100, a detector 200, a corrector 300, a controller 400, and an EPC 500, as shown in FIGS. 1 and 3.

The turret unwinder 100 may have the working and standby rolls 1 and 2 rotatably coupled thereto, and may unwind a sheet from the working roll 1 while allowing the working roll 1 to be rotated. When the working roll 1 runs out of the sheet, the turret unwinder 100 allows sheets to be spliced to each other by using an auto splicer while switching the positions of the standby and working rolls 2 and 1 to each other. Then, the turret unwinder 100 may unwind a sheet while allowing the standby roll 2, the position of which has been switched, to perform the function of the working roll 1.

More specifically, the turret unwinder 100 may be provided with fixation chucks 110 that can rotatably mount the axial ends of the working and standby rolls 1 and 2, i.e., the axial ends of the paper tubes 3 constituting parts of the working and standby rolls 1 and 2, on a pair of turret bodies 102 that rotate around a rotation shaft 101.

This turret unwinder 100 allows the auto splicer to splice sheets when the working roll 1 runs out of a sheet. After the sheet splicing is completed, the turret unwinder 100 switches the positions of the working and standby rolls 1 and 2 through the rotation of the rotation shaft 101 via the controller 400. The turret unwinder 100 allows the sheet of the standby roll 2, which has been moved to the position of the working roll 1, to be unwound and supplied. The turret unwinder 100 may allow the working roll 1 having run out of the sheet, which has been moved to the position of the standby roll 2, to be replaced. That is, after the sheet splicing has been completed, the standby roll 2 moves to the position of the working roll 1 and functions as a new working roll 1, and the working roll 1 having run out of the sheet may then move to the position of the standby roll 2 and be replaced with a new standby roll 2.

In this case, the turret unwinder 100 may allow the standby roll 2 to be automatically loaded and mounted onto the fixation chuck 110 via an auto mobile robot (AMR) system in the state of being loaded onto a cart 5, as shown in FIGS. 1 and 2.

Meanwhile, the fixation chucks 110 may each be formed of mechanical chucks that allow the standby and working rolls 2 and 1 to be axially movable while fixing the axial ends of each of the standby and working rolls 2 and 1, i.e., both axial ends of each of the paper tubes 3.

These fixation chucks 110 are installed on the turret bodies 102 of the turret unwinder 100, and may be axially movable along the axes of the standby and working rolls 2 and 1. The fixation chucks 110 may fix both ends of the shafts, which are coupled to the paper tubes constituting the central axes of the standby and working rolls 2 and 1, via structures in each of which a plurality of jaws are selectively opened or closed.

Furthermore, the fixation chucks 110 may fix the standby and working rolls 2 and 1 while being automatically operated, and may fix the standby and working rolls 2 and 1 while being manually operated by an operator.

The detector 200 is configured to detect the position of an axial end of the standby roll 2 mounted on the turret unwinder 100 and provide the information to the controller 400, thereby aligning the sheet of the standby roll 2 and the sheet 4 of the working roll 1 with each other. The detector 200 is further configured to detect the meandering of the sheet 4 being unwound from the working roll 1.

More specifically, the detector 200 may perform the following functions:

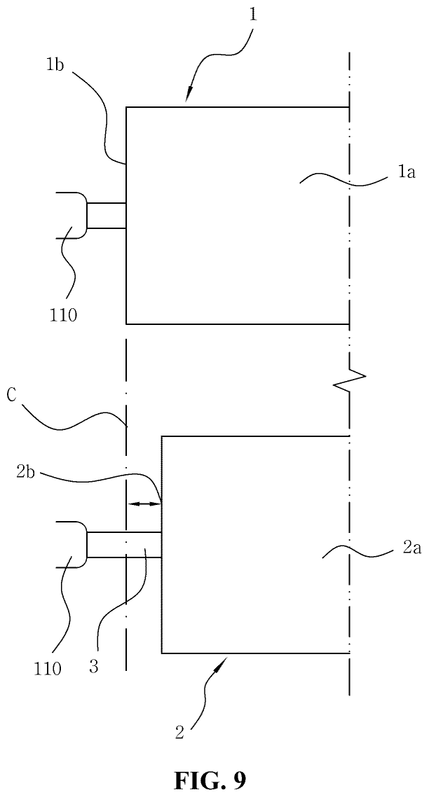

First, the detector 200 may function to detect the position of the axial end 2b of the roll portion 2a of the sheet constituting the standby roll 2 and provide the information to the controller 400, as shown in FIG. 9, so that the corrector 300 to be described later can correct the position of the standby roll 2 so that the sheets of the standby and working rolls 2 and 1 are aligned with each other during the process of splicing the sheets of the standby and working rolls 2 and 1 to each other via the auto splicer.

Second, the detector 200 may function to detect the position of an axial end of the paper tube 3 constituting a part of the standby roll 2 and provide the information to the controller 400 so that the position of the fixation chuck 110 can be corrected with respect to the position of the paper tube 3 constituting a part of the standby roll 2 during the process of loading the standby roll 2 onto the turret unwinder 100 and mounting it on the fixation chuck 110.

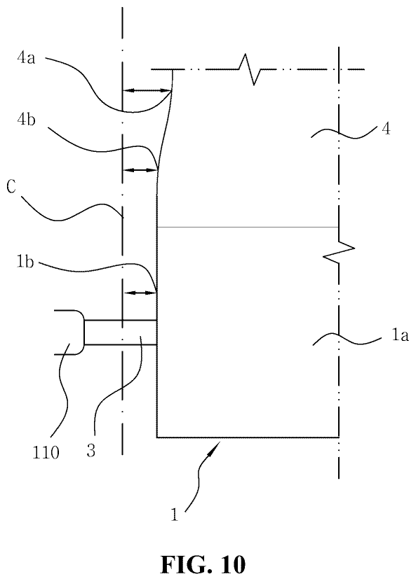

Third, the detector 200 may function to detect a change in the position of the sheet 4 being unwound from the roll portion 1a of the working roll 1 and provide the information to the controller 400 so that the position of the working roll 1 can be corrected via the corrector 300 to be described below when during the process in which the sheet 4 is unwound from the working roll 1, the sheet 4 is unwound from the working roll 1 in a rectilinear line, but gradually moves in a meandering manner in a direction, either toward or away from the fixation chuck 110, as it moves away from the roll portion 1a, as shown in FIG. 10.

As one embodiment for performing the above-described functions, the detector 200 may be configured to include at least one vision sensor 220 disposed adjacent to the standby roll 2 and at least one edge profile sensor 240 disposed adjacent to the working roll 1, as shown in FIG. 1.

In this case, the detector 200 may detect the position of the axial end 2b of the roll portion 2a constituting a part of the standby roll 2 via the vision sensor 220 in order to align the sheets of the standby and working rolls 2 and 1 via the corrector 300 to be described later in the process of splicing the sheets of the standby and working rolls 2 and 1 to each other. Furthermore, the detector 200 may detect the position of an edge of the sheet 4 being unwound from the working roll 1 via the edge profile sensor 240 and provide the information to the controller 400 in order to detect the meandering of the sheet 4 being unwound from the working roll 1.

In this case, in the case of loading and mounting the standby roll 2 onto the turret unwinder 100, the vision sensor 220 may detect an end of the paper tube 3 of the standby roll 2 before mounting the paper tube 3 on the fixation chuck 110 and apply the information to the controller 400.

Furthermore, the edge profile sensor 240 may continuously detect the edge of the sheet 4 being unwound from the working roll 1 or periodically detect it at preset time intervals and may provide the information to the controller 400, thereby providing the position of the edge 4a at a preceding measurement point and the position of the edge 4b at a subsequent measurement point. Through this, when the position of the edge is detected as gradually moving in a specific direction, as in the case where the position of the edge 4a at the preceding measurement point and the position of the edge 4b at the subsequent measurement point are detected as departing from a set deviation, the controller 400 to be described later may determine that the sheet 4 being unwound from the working roll 1 is meandering and may adjust the position of the working roll 1 via the corrector 300 to adjust the unwinding angle of the sheet 4.

Furthermore, as another embodiment for performing the above-described functions, the detector 200 may be configured to include at least one vision sensor 220 and an additional edge profile sensor 250 disposed adjacent to the standby roll 2 and an edge profile sensor 240 disposed adjacent to the working roll 1, as shown in FIG. 2.

In this case, the detector 200 may detect the position of the axial end 2b of the roll portion 2a of the standby roll 2 during the process of splicing the sheets of the standby and working rolls 2 and 1 to each other via the vision sensor 220 and the additional edge profile sensor 250 disposed adjacent to the standby roll 2, and may detect an end of the paper tube 3 of the standby roll 2 before the paper tube 3 is mounted on the fixation chuck 110. Furthermore, the detector 200 may continuously detect the position of the edge of the sheet 4 being unwound from the working roll 1 via the edge profile sensor 240 disposed adjacent to the working roll 1, thereby detecting a change in the position of the edge.

Meanwhile, the vision sensor 220 and the edge profile sensor 240 may constitute the detector 200 together with a sensor support 210 and a sensor movement member 230, as shown in FIG. 4.

The sensor support 210 is configured to dispose the vision sensor 210 at a location adjacent to the turret unwinder 100 while supporting the vision sensor 220 or edge profile sensor 240 at a predetermined height.

This sensor support 210 may be formed of a plurality of bars having a predetermined length and support the vision sensor 220 or edge profile sensor 240 through the medium of the sensor movement member 230 to be described later.

In this case, the sensor support 210 may be equipped with casters (not shown) at the bottom thereof to enable movement, and may be formed in a telescopic structure to adjust the height of the vision sensor 220 and be selectively increased and decreased in the length thereof.

The sensor movement member 230 is configured to be installed on the sensor support 210 and allow the vision sensor 220 or edge profile sensor 240 to move under the control of the controller 400 while connecting the vision sensor 220 or edge profile sensor 240 to the sensor support 210.

That is, the positions of the vision sensor 220 and the edge profile sensor 240 may be precisely adjusted through the operation of the sensor movement member 230 in the state of being coupled to the sensor movement member 230 and disposed outside the standby roll 2.

The sensor movement member 230 may be configured to include a sensor rail 231 and a sensor slider 232.

The sensor rail 231 may guide the vision sensor 220 through a movement path in the state of being installed on the sensor support 210, and the sensor slider 232 may move the vision sensor 220 while moving along the sensor rail 231 in such a manner that the vision sensor 220 is fixed to the sensor slider 232 in the state in which the sensor slider 232 is movably coupled to the sensor rail 231.

The sensor rail 231 and the sensor slider 232 may be formed in, for example, a linear motor structure or ball screw structure and move the vision sensor 220 through the rectilinear movement of the sensor slider 232.

In this case, the sensor rail 231 may be formed in a single-axis structure extending vertically, as shown in FIG. 4, and may adjust the height of the vision sensor 220 or edge profile sensor 240 while moving the sensor slider 232 in a direction perpendicular to the tangent line of the standby roll 2. Unlike in the shown structure, the sensor rail may be formed in a two-axis or three-axis structure, and may adjust the position of the vision sensor 220 or edge profile sensor 240 while moving the sensor slider 232 in each axis direction.

Meanwhile, the edge profile sensor 240 may be installed on a separate support while being disposed adjacent to the working roll 1. In some cases, the edge profile sensor 240 may be installed to be movable in all directions, such as up, down, left, and right directions, thereby detecting a change in the position of the edge of the sheet 4 being unwound from the working roll 1 and providing the information.

In this case, the edge profile sensor 240 may be formed of a laser sensor or ultrasonic sensor, and may detect the edge of the sheet being unwound from the working roll 1. Like the vision sensor 220, the edge profile sensor 240 may detect the edge of the sheet of the working roll 1 through photographing.

As shown in FIG. 10, this edge profile sensor 240 may detect whether the sheet 4 of the working roll 1 is unwound in a rectilinear line by detecting whether there is a change between the position of the edge 4a at the preceding measurement point and the position of the edge 4b at the subsequent measurement point change while continuously detecting the edge of the sheet 4, being unwound from a new working roll 1 for which sheet splicing has been completed, at the set same position. To this end, the edge profile sensor 240 may continuously detect the edge of the sheet 4 of the working roll 1 or periodically detect it at preset time intervals, and may provide the information to the controller 400.

Meanwhile, the vision sensor 220 may be formed of a single sensor and detect the position of the outer edge of the standby roll 2 and the position of an end of the paper tube 3 of the standby roll 2. Alternatively, the vision sensor 220 may be formed of a plurality of sensors, one of them may detect the position of an end of the roll portion 2a constituting a part of the standby roll 2 and the other sensor may detect the position of an end of the paper tube 3 constituting a part of the standby roll 2, and the sensors may apply the information to the controller 400.

The corrector 300 is configured to correct the position of the standby roll 2 while moving the above-described fixation chuck 110 in the axial direction. The corrector 300 may align the end 2b of the roll portion 2a constituting a part of the standby roll 2 with the end 1b of the roll portion 1a constituting a part of the working roll 1 by moving the fixation chuck 110 in the axial direction under the control of the controller 400.

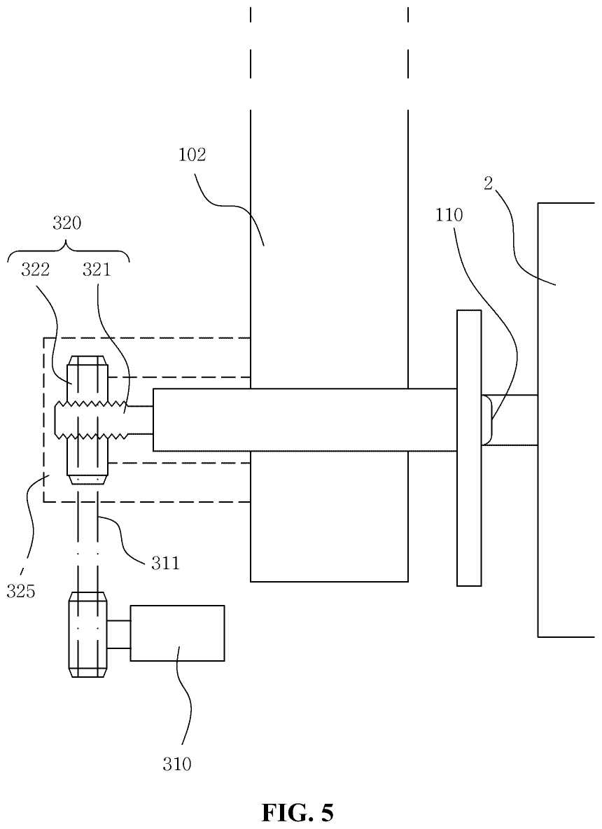

This corrector 300 may be configured to include a servomotor 310 and a connection member 320, as shown in FIG. 5.

The servomotor 310 may be connected to at least one of the pair of fixation chucks 110 that fix the standby roll 2, and may move the fixation chuck 110 in the axial direction while rotating at a rotational speed set by the controller 400.

The connection member 320 is a member that moves the fixation chuck 110 rectilinearly in the axial direction of the standby roll 2 through the rotational movement of the servomotor 310 while connecting the servomotor 310 and the fixation chuck 110 to each other.

As shown in FIG. 5, this connection member 320 may move the mechanical chuck rectilinearly through the rotational movement of the servomotor 310 via the structure of a male screw 321 and a female screw 322.

More specifically, the male screw 321 may be provided on the fixation chuck 110 and move together with the fixation chuck 110.

The female screw 322 may be connected to the servomotor 310 in the state of being screw-coupled to the male screw 321. The female screw 322 may move the male screw 321 rectilinearly while being rotated forward or reversely by the operation of the servomotor 310.

This female screw 322 may be screw-connected to the male screw 321 in the state of being rotatable idly within a housing 325 fixed to the turret body 102. Alternatively, the female screw 322 may be connected to the servomotor 310 via a power transmission member 326 such as a chain, a belt, or a gear.

That is, the female screw 322 may be operated in conjunction with the servomotor 310 via the power transmission member 326 when the servomotor 310 rotates, and may rotate idly in either the forward or reverse direction. Accordingly, the male screw 321 may move the fixation chuck 110 in the axial direction while being moved in a rectilinear direction by the rotation of the female screw 322.

Meanwhile, the connection member 320 may be formed in a structure in which the male screw 321 and the female screw 322 are arranged in opposite positions, unlike in the structure shown in FIG. 5. That is, the female screw 322 may be provided on the fixation chuck 110 and move together with the fixation chuck 110. The male screw 321 may be coupled to the female screw 322 to be rotated idly by the servomotor 310 in the state of being screw-coupled to the female screw 322 and be rotated idly in either the forward or reverse direction, thereby moving the fixation chuck 110 axially while moving the female screw 322 rectilinearly.

The controller 400 is configured to align the sheet of the standby roll 2 with the sheet of the working roll 1 while correcting the position of the standby roll 2 by controlling the operation of the corrector 300 based on the position information detected by the above-described detector 200. Furthermore, the controller 400 is configured to splice the sheet of the standby roll 2 onto the working roll 1 while controlling the auto splicer.

As shown in FIG. 1, this controller 400 may be formed of a conventional information processing device capable of data processing such as data collection and data computation, may control the operations of the turret unwinder 100, the detector 200, the auto splicer, and the corrector 300 while communicating with them, and may be installed on a portion of the turret unwinder 100.

More specifically, the controller 400 may be formed together with an input/output interface 410, memory 420, and a communication interface 430, as shown in FIG. 6.

The input/output interface 410 may include an input interface for receiving input from a user and an output interface for displaying the operating status of each of the turret unwinder 100, the detector 200, the auto splicer, and the corrector 300.

For example, the input interface may include an operation panel that receives user input. The output interface may include a display that displays the end 2b of the sheet portion 2a constituting a part of the standby roll 2 and the end 1b of the sheet portion 1a constituting a part of the working roll 1 detected by the detector 200 and the operating status of each of the turret unwinder 100 and the corrector 300.

Furthermore, the input interface may include devices capable of receiving various types of user input, such as a keyboard, physical buttons, a touch screen, a camera, and a microphone.

The memory 420 may install and store various types of data, such as a file, an application, and a program, and may store the data acquired by the detector 200. Furthermore, the memory may store a program capable of adjusting the position of the standby roll 2 while controlling the operation of the corrector 300 based on the data acquired by the detector 200.

The controller 400 may control the overall operation of the turret unwinder 100, the detector 200, the auto splicer, and the corrector 300, and may include a processor such as a CPU or GPU.

Furthermore, the controller 400 may execute a program stored in the memory 420, may read data regarding the information acquired by the detector 200 out of the information stored in the memory 420, or may store new data in the memory 420.

In this case, the controller 400 may adjust the position of the standby roll 2 in two manners while controlling the corrector 300.

More specifically, referring to FIG. 9, as one embodiment, the controller 400 may align the sheet of the standby roll 2 with the sheet of the working roll 1 by moving the end 2b of the standby roll 2 so that it is aligned with the end 1b of the working roll 1 while detecting only the end 2b of the roll portion 2a of the standby roll 2 via the detector 200.

In this case, when the working roll 1 is present in a previous process, i.e., when the working roll 1 is present at the position of the standby roll 2, it is present at the position detected by the detector 200 or is present at a position for correcting the meandering of the sheet 4 after being switched to the position of the working roll 1. Accordingly, the controller 400 may detect only the position of the end 2b of the standby roll 2 and move the end 2b of the standby roll 2 to a position corresponding to the preset position of the working roll 1.

In this case, when the deviation between the position of the end 2b of the standby roll 2, detected by the detector 200, and the position of the end 1b of the preset working roll 1a is equal to or larger than a predetermined value, the controller 400 may align the working and standby rolls 1 and 2 with each other by moving the standby roll 2 axially via the corrector 300.

Furthermore, as another embodiment that controls the position of the standby roll 2, the controller 400 may move the axial end 2b of the sheet portion 2a of the standby roll 2, detected by the detector 200, to a preset reference position C through the control of the corrector 300. That is, the controller 400 may move the axial end 2b of the sheet portion 2a of the standby roll 2 to the preset position C through the axial movement of the fixation chuck 110, thereby aligning it with the axial end 1b of the sheet portion 1a of the working roll 1, which is already positioned at the preset reference position C.

In this case, the working roll 1 has been aligned to the reference position C at a position corresponding to the standby roll 2 in the previous process, so that in the case where the standby roll 2 moves to the reference position C in a current process, the ends of the working and standby rolls 1 and 2 can be aligned with each other. Even in this case, the working and standby rolls 1 and 2 may be aligned with each other by detecting the position of the end 2b of only the standby roll 2 via the detector 200.

Meanwhile, when the standby roll 1 is mounted on the turret unwinder 100, the controller 400 may detect the position of the end of the paper tube 3 constituting a part of the standby roll 1 via the detector 200, may measure the tolerance with respect to the position of the paper tube of the working roll 1 mounted in a previous process or the set position of the paper tube, and may then adjust the position of the fixation chuck 110 through the control of the corrector 300.

Furthermore, the controller 400 may perform wired/wireless communication with another device or a network via the configuration of the communication interface 430.

To this end, the communication interface 430 may include a communication interface that supports at least one of various wired/wireless communication methods. For example, the communication interface may be implemented in the form of a chipset.

In this case, the wireless communication supported by the communication interface 430 may include, for example, Wireless Fidelity (Wi-Fi), Wi-Fi Direct, Bluetooth, Ultra-Wideband (UWB), Near Field Communication (NFC), and/or the like. Furthermore, the wired communication supported by the communication interface may include, for example, Universal Serial Bus (USB), High Definition Multimedia Interface (HDMI), and/or the like.

Furthermore, after the sheets have been spliced by the auto splicer, the controller 400 may detect the edge of the sheet 4 being unwound from the standby roll 2 switched to the position of the working roll 1, i.e., a new working roll 1, via the edge profile sensor 240, and may control the corrector 300 based on a detection result to move the working roll 1 in the axial direction so that the sheet 4 can be unwound in a rectilinear line.

In this case, the controller 400 may continuously detect the edge of the sheet 4 being unwound from the working roll 1 or periodically detect it at preset time intervals at a set position via the edge profile sensor 240. When the deviation between the position of the edge 4a at a preceding measurement point and the position of the edge 4b at a subsequent measurement point is equal to or larger than a set value, as shown in FIG. 10, the controller 400 may determine that the unwound sheet 4 is meandering, and may correct the unwinding angle of the sheet 4 of the working roll 1 while moving the fixation chuck 110 on which the working roll 1 is mounted in the axial direction via the corrector 300.

In this case, the controller 400 may move the working roll 1 so that the end 1b of the roll portion 1a of the working roll 1, previously set in a previous process, corresponds to the edge 4a at the preceding measurement point while moving the fixation chuck 110 equipped with the working roll 1, thereby performing adjustment so that the edge of the sheet 4 being wound from the working roll 1 is aligned with the point 4a.

The edge position controller (EPC) 500 is configured to adjust the unwinding angle of the sheet being unwound from the working roll 1 by moving the overall turret unwinder 100 in the axial direction of the working roll 1 under the control of the controller 400 while movably supporting the bottom of the turret unwinder 100, as shown in FIGS. 1 and 2.

This EPC 500 may be configured to include supports 510 configured to support the bottoms of the turret unwinder 100 on both sides thereof, and movable blocks 520 fixed to the bottom of the turret unwinder 100 in the state of being movably installed on top of the supports 510.

In this case, the movable blocks 520 may be coupled to the bottoms of the supports 510 via actuator or ball screw structures to enable movement in the XY-axis direction. The movable blocks 520 may adjust the unwinding angle of the sheet by moving the turret unwinder 100 while moving through the control of the controller 400.

Meanwhile, when the working roll 1 runs out of a sheet and is then switched to the position of the standby roll 2, there occurs a phenomenon in which the fixation chuck 110 may not be smoothly detached from the paper tube during the process in which the fixation chuck 110 is separated.

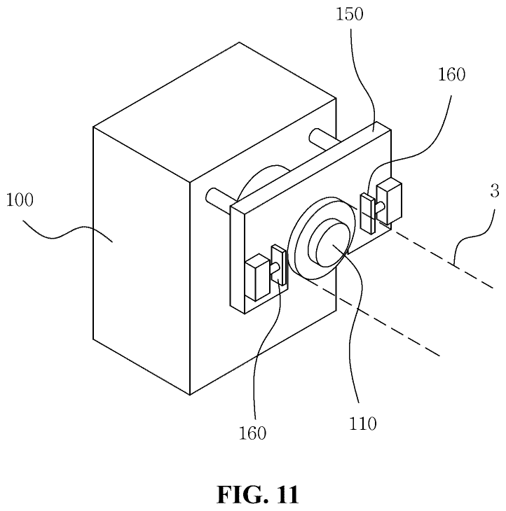

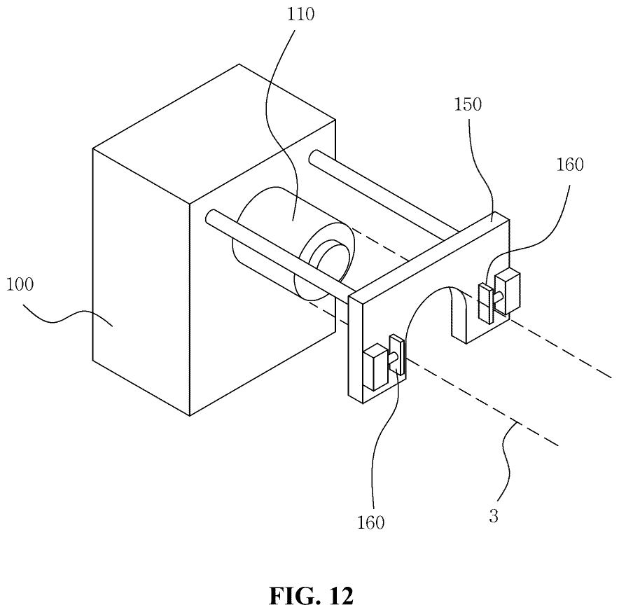

To overcome this problem, a sheet supply apparatus 10 according to one embodiment may be configured to further include a clamp fixation plate 150 and a paper tube clamp 160, as shown in FIGS. 11 and 12.

The clamp fixation plate 150 may be retractably installed on the turret unwinder 100, and may be operated by the controller 400 when the sheet is depleted. The clamp fixation plate 150 may protrude in a direction parallel to the paper tube 3 together with the paper tube clamp 160 to be described later.

This clamp fixation plate 150 is installed on the turret unwinder 100 via a hydraulic or pneumatic cylinder. When the working roll 1 runs out of the sheet, the clamp fixation plate 150 is moved in a direction parallel to the paper tube 3 and positioned in the middle of the paper tube 3 through the operation of the cylinder by the controller, as shown in FIG. 12.

The above-described paper tube clamp 160 is configured to apply pressure to and fix the paper tube 3 having run out of the sheet while moving together with the clamp fixation plate 150, thereby allowing the fixation chuck 110 to be separated from the paper tube 3.

At least one paper tube clamp 160 may be installed on the clamp fixation plate 150 and have a structure that can protrude through the control of the controller 400, thereby applying pressure to and fixing the paper tube 3 while protruding toward the paper tube 3.

In this case, the paper tube clamp 160 may be installed on the clamp fixation plate 150 while forming a pair of parts facing each other, as shown in FIG. 12. The paper tube clamp 160 may apply pressure to and fix the paper tube 3 in the form of gripping the paper tube 3 while protruding toward the paper tube 3 via a structure such as an actuator or step motor.

Accordingly, the fixation chuck 110 may be smoothly separated from the paper tube 3 while moving to a side opposite the paper tube 3 fixed by the paper tube clamp 160.

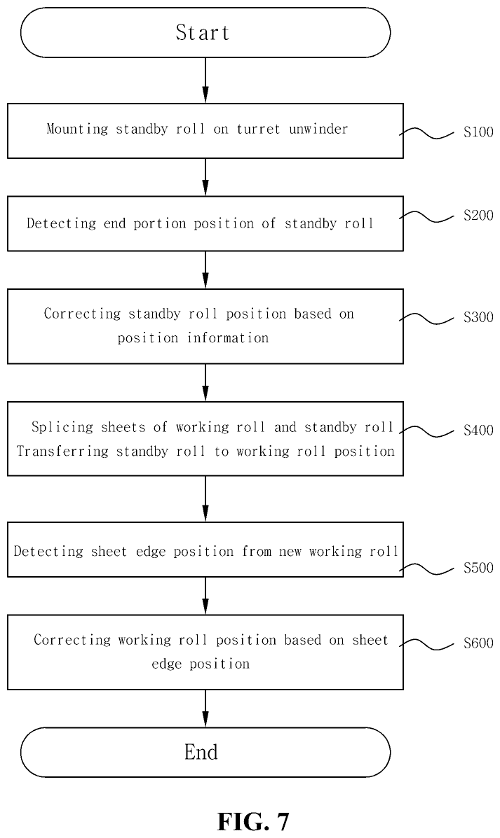

A sheet supply method using the sheet supply apparatus 10 according to one embodiment, including the above-described components, will be described with reference to FIG. 7.

The sheet supply apparatus 10 according to one embodiment may be applied to the process of manufacturing solar modules. More specifically, it may be applied prior to the process of continuously supplying EVA (Ethyl Vinyl Acetate) sheets used in solar modules, cutting the EVA sheets, and stacking them in solar modules.

The standby roll 2 may be loaded and mounted onto the turret unwinder 100 from which the sheet of the working roll 1 is being unwound in step S100.

In this case, the standby roll 2 may be moved by an autonomous mobile robot (AMR) in the state of being stacked on the movable cart 5 and mounted on the turret unwinder 100, and both ends of the paper tube 3 may be fixed to the fixation chuck 110 provided as mechanical chucks on the turret bodies 102 constituting parts of the turret unwinder 100.

Additionally, during the process of mounting the standby roll 2 on the turret unwinder 100, the controller 400 may detect the position of an end of the paper tube 3 constituting a part of the standby roll 2 via the detector 200, may measure the tolerance with respect to the position of the paper tube of the working roll 1 mounted at the position of the standby roll 1 in a previous process or the set position of the paper tube, and may then adjust the position of the fixation chuck 110 through the control of the corrector 300, thereby mounting the standby roll 2 on the fixation chuck 110 of the turret unwinder 100.

The position of the axial end 2a of the roll portion 2a constituting a part of the standby roll 2 may be detected by the vision sensor 220 constituting a part of the detector 200 of the controller 400 in step S200.

In this case, as shown in FIG. 9, the controller 400 may derive the deviation between the information about the position of the end 2a of the standby roll 2 provided by the detector 200 and the information about the position of the working roll 1 preset in a previous process or the position information set to correct the meandering of the sheet 4 of the working roll 1, and, when the derived deviation exceeds a preset value, may perform correction by aligning the roll portion 2a of the standby roll 2 with the roll portion 1a of the working roll 1 while controlling the corrector 300 in step S300.

Alternatively, in some cases, the controller 400 may derive the deviation between the information about the position of the end 2b of the standby roll 2 and the preset reference position C, and may control the corrector 300 to align the standby and working rolls 2 and 1 with each other.

In this case, the servomotor 310 may rotate the female screw 322 while being controlled by the controller 400. The male screw 321 may be moved linearly by the rotation of the female screw 322, thereby correcting the axial position of the standby roll 2 while moving the standby roll 2 in the axial direction.

The controller 400 may control the auto splicer to splice the sheets of the working and standby rolls 1 and 2 to each other after the position of the standby roll 2 has been corrected and may also control the turret unwinder 100 to switch the positions of the standby and working rolls 2 and 1 with each other after the sheets have been spliced to each other in step S400.

In addition, the edge profile sensor 240 may detect the edge of the sheet 4 being unwound from the new working roll 1 whose position has been changed and apply the detected information to the controller 400 in step S500.

In this case, the controller 400 may continuously measure and detect the edge of the sheet 4 being unwound from the working roll 1 or periodically measure and detect it at preset time intervals with the edge profile sensor 240. When the deviation between the edge 4a at the preceding measurement point and the edge 4b at the subsequent measurement point is equal to or larger than a set value, the controller 400 may determine that the unwound sheet 4 is meandering.

When the controller 400 determines that the sheet 4 being unwound from the working roll 1 is meandering based on a detection signal from the edge profile sensor 240, the controller 400 may correct the position of the standby roll 2 based on information about a change in the position of the edge of the sheet 4 detected by the edge profile sensor 240 in step S600.

In this case, the controller 400 may control the corrector 300 to move the fixation chuck 110 equipped with the working roll 1 in the axial direction, thereby moving the working roll 1 so that the end 1b of the roll portion 1a of the working roll 1, previously set in the previous process, corresponds to the edge 4a at the preceding measurement point. Additionally, the controller 400 may control the EPC 500 to move the overall turret unwinder 100 in the axial direction of the working roll 1, thereby moving the end 1b of the roll portion 1a of the working roll 1 so that it corresponds to the edge 4a at the preceding measurement point.

In this case, the controller 400 may correct the position of the working roll 1 while moving the fixation chuck 110 in the axial direction through the control of the servomotor 310. Additionally, the controller 400 may move the position of the turret unwinder 100 in the axial direction of the working roll 1 by controlling the operation of the EPC 500, thereby adjusting the unwinding angle of the sheet 4 of the working roll 1.

Accordingly, the axial position of the working roll 1 may be corrected depending on the degree of the meandering of the sheet 4.

As described above, according to the sheet supply apparatus 10 according to one embodiment, the controller 400 may detect the position of the end 2b of the roll portion 2a of the standby roll 2 through the detector 200, and may moves the fixation chuck 110 fixing the standby roll 2 in the axial direction through the corrector 300, thereby accurately aligning the sheet of the standby roll 2 to be in line with the sheet of the working roll 1.

The term “unit” used in the above-described embodiments means software or a hardware component such as a field-programmable gate array (FPGA) or application-specific integrated circuit (ASIC), and a “unit” performs a specific role. However, a “unit” is not limited to software or hardware. A “unit” may be configured to be present in an addressable storage medium, and also may be configured to run one or more processors. Accordingly, as an example, a “unit” includes components, such as software components, object-oriented software components, class components and task components, processes, functions, attributes, procedures, subroutines, segments in program code, drivers, firmware, microcode, circuits, data, a database, data structures, tables, arrays, and variables.

Components and a function provided in “unit(s)” may be coupled to a smaller number of components and “unit(s)” or divided into a larger number of components and “unit(s).”

In addition, components and “unit(s)” may be implemented to run one or more central processing units (CPUs) in a device or secure multimedia card.

The sheet supply method according to the embodiment described through FIG. 7 may be implemented in the form of a computer-readable medium that stores instructions and data that can be executed by a computer. In this case, the instructions and the data may be stored in the form of program code, and may generate a predetermined program module and perform a predetermined operation when executed by a processor. Furthermore, the computer-readable medium may be any type of available medium that can be accessed by a computer, and may include volatile, non-volatile, separable and non-separable media. Furthermore, the computer-readable medium may be a computer storage medium. The computer storage medium may include all volatile, non-volatile, separable and non-separable media that store information, such as computer-readable instructions, a data structure, a program module, or other data, and that are implemented using any method or technology. For example, the computer storage medium may be a magnetic storage medium such as an HDD, an SSD, or the like, an optical storage medium such as a CD, a DVD, a Blu-ray disk or the like, or memory included in a server that can be accessed over a network.

Furthermore, the sheet supply method according to the embodiment described through FIG. 7 may be implemented as a computer program (or a computer program product) including computer-executable instructions. The computer program includes programmable machine instructions that are processed by a processor, and may be implemented as a high-level programming language, an object-oriented programming language, an assembly language, a machine language, or the like. Furthermore, the computer program may be stored in a tangible computer-readable storage medium (for example, memory, a hard disk, a magnetic/optical medium, a solid-state drive (SSD), or the like).

Accordingly, the sheet supply method according to the embodiment described through FIG. 7 may be implemented in such a manner that the above-described computer program is executed by a computing apparatus. The computing apparatus may include at least some of a processor, memory, a storage device, a high-speed interface connected to memory and a high-speed expansion port, and a low-speed interface connected to a low-speed bus and a storage device. These individual components are connected using various buses, and may be mounted on a common motherboard or using another appropriate method.

In this case, the processor may process instructions within a computing apparatus. An example of the instructions is instructions which are stored in memory or a storage device in order to display graphic information for providing a Graphic User Interface (GUI) onto an external input/output device, such as a display connected to a high-speed interface. As another embodiment, a plurality of processors and/or a plurality of buses may be appropriately used along with a plurality of pieces of memory. Furthermore, the processor may be implemented as a chipset formed of chips including a plurality of independent analog and/or digital processors.

Furthermore, the memory stores information within the computing device. As an example, the memory may include a volatile memory unit or a set of the volatile memory units. As another example, the memory may include a non-volatile memory unit or a set of the non-volatile memory units. Furthermore, the memory may be another type of computer-readable medium, such as a magnetic or optical disk.

In addition, the storage device may provide a large storage space to the computing device. The storage device may be a computer-readable medium, or may be a configuration including such a computer-readable medium. For example, the storage device may also include devices within a storage area network (SAN) or other elements, and may be a floppy disk device, a hard disk device, an optical disk device, a tape device, flash memory, or a similar semiconductor memory device or array.

According to any one of the above-described solutions, there may be proposed the sheet supply apparatus and method that may splice the leading edge of a sheet wound on a standby roll to the trailing edge of a sheet being unwound from a working roll by using an auto splicer, and may align and correct the axial end of the standby roll so that it is aligned with the axial end of the working roll, thereby improving the work efficiency and precision of sheet splicing.

Furthermore, according to any one of the above-described solutions, the controller may detect the axial end of a standby roll via the detector, and may move the fixation chuck, fixing the ends of the standby roll, in the axial direction via the corrector, thereby accurately aligning and splicing the sheet portion of the standby roll so that it is aligned with the sheet portion of the working roll.

Furthermore, according to any one of the above-described solutions, the fixation chuck for fixing the end of a standby roll may be constructed using an axially movable mechanical chuck, and the mechanical chuck may be accurately moved via the configuration of the servomotor, thereby precisely splicing the end of the standby roll to the end of the working roll while aligning the end of the standby roll with the end of the working roll.

Furthermore, according to any one of the above-described solutions, the vision sensor constituting a part of the detector is moved via the sensor movement member, so that the end of a standby roll may be accurately detected and provided.

Furthermore, according to any one of the above-described solutions, when a standby roll has been switched to the position of a working roll and then a sheet is unwound from a new working roll, the controller operates the corrector based on the edge of the sheet of the working roll detected via the edge profile sensor, thereby correcting the meandering of the sheet of the working roll in the case where the sheet of the working roll is meandering during an unwinding process.

Furthermore, according to any one of the above-described solutions, the controller may simultaneously control the operation of the EPC, movably supporting the turret unwinder, while controlling the corrector based on a detection signal from the detector, thereby precisely correcting the unwinding angle of the sheet of a working roll while more precisely correcting the position of the working roll.

Furthermore, according to any one of the above-described solutions, the paper tube clamp provided on the clamp fixation plate may apply pressure to and fix a paper tube while moving together with the clamp fixation plate, thereby allowing the fixation chuck to be smoothly separated from the paper tube.

The advantages that can be achieved by the embodiments disclosed herein are not limited to the advantages described above, and other advantages not described above will be clearly understood by those having ordinary skill in the art, to which the embodiments disclosed herein pertain, from the foregoing description.

The above-described embodiments are intended for illustrative purposes. It will be understood that those having ordinary knowledge in the art to which the present invention pertains can easily make modifications and variations without changing the technical spirit and essential features of the present invention. Therefore, the above-described embodiments are illustrative and are not limitative in all aspects. For example, each component described as being in a single form may be practiced in a distributed form. In the same manner, components described as being in a distributed form may be practiced in an integrated form.

The scope of protection pursued through the present specification should be defined by the attached claims, rather than the detailed description. All modifications and variations which can be derived from the meanings, scopes and equivalents of the claims should be construed as falling within the scope of the present invention.

What is claimed is:

1. A sheet supply apparatus for continuously supplying sheets while splicing a leading edge of a sheet of a standby roll to a trailing end of a sheet being unwound from a working roll by using an auto splicer, the sheet supply apparatus comprising:
a turret unwinder provided with fixation chucks that each fix both ends of a paper tube forming a central axis of each of the working and standby rolls so that the working and standby rolls can be rotatably mounted thereon to allow unwinding of the sheets, and configured to switch positions of the standby and working rolls to each other when the working roll runs out of the sheet;
a detector configured to detect a position of one of both axial ends of the standby roll mounted on the turret unwinder;
a corrector configured to be connected to each of the fixation chucks constituting parts of the turret unwinder and to correct a position of the standby roll by moving the fixation chuck in an axial direction; and
a controller configured to align an end of the standby roll so that the end of the standby roll is aligned with the end of the working roll while correcting the position of the standby roll by controlling an operation of the corrector based on information about the position of the standby roll detected by the detector.

2. The sheet supply apparatus of claim 1, wherein:
the fixation chuck comprises a pair of mechanical chucks installed to allow the standby roll to move axially while fixing both ends of a paper tube of the standby roll; and
the corrector comprises:
a servomotor configured to be connected to one of the pair of mechanical chucks and to rotate at a rotational speed set by the controller; and
a connection member configured to linearly move the mechanical chuck in an axial direction of the standby roll through rotational movement of the servomotor while connecting the servomotor and the mechanical chuck to each other.

3. The sheet supply apparatus of claim 2, wherein the connection member comprises:
one of a male screw and a female screw provided on the mechanical chuck; and
a remaining one of the male screw and the female screw configured to be connected by the servomotor in a state of being screw-coupled to the one screw and to linearly move the one screw while being rotated forward or reversely by an operation of the servomotor.

4. The sheet supply apparatus of claim 1, wherein the detector comprises:
a sensor support installed adjacent to the turret unwinder;
at least one vision sensor configured to be connected to the sensor support and to capture an image of at least one of the axial end of the standby roll and the end of the paper tube of the standby roll and provide the captured image to the controller; and
a sensor movement member installed on the sensor support, and configured to allow movement of the vision sensor by the controller while connecting the vision sensor and the sensor support to each other.

5. The sheet supply apparatus of claim 4, wherein the detector further comprises at least one edge profile sensor configured to detect an edge of the sheet being unwound from the working roll after the standby roll has been switched to a position of the working roll.

6. The sheet supply apparatus of claim 5, wherein the controller adjusts an unwinding angle of the sheet being unwound from the working roll while correcting the position of the working roll by operating the corrector based on a detection signal from the edge profile sensor.

7. The sheet supply apparatus of claim 6, further comprising an edge position controller (EPC) configured to allow the turret unwinder to move in an axial direction of the working roll through controlling of the controller while supporting a bottom of the turret unwinder;
wherein the controller adjusts an unwinding angle of a sheet of the working roll while controlling operations of the corrector and the EPC based on a detection signal received from the edge profile sensor.

8. The sheet supply apparatus of claim 1, further comprising:
a clamp fixation plate provided on the turret unwinder, and configured to be operated when the working roll runs out of the sheet and protrude in a direction parallel to the paper tube where the sheet is depleted; and
at least one paper tube clamp provided on the clamp fixation plate, and configured to protrude toward the paper tube and allow the fixation chuck to be separated from the paper tube while applying pressurize to and fixing the paper tube.

9. A sheet supply method, the sheet supply method being performed by a sheet supply apparatus for continuously supplying sheets while splicing a leading edge of a sheet of a standby roll to a trailing end of a sheet being unwound from a working roll by using an auto splicer, the sheet supply method comprising:
loading and mounting the standby roll onto a turret unwinder mounted with the working roll;
detecting a position of one of both axial ends of the standby roll mounted on the turret unwinder; and
correcting a position of the standby roll while moving the standby roll axially so that an end of the standby roll is aligned with an end of the working roll based on information about the position of the standby roll detected in the detecting.

10. The sheet supply method of claim 9, wherein:
the loading and mounting the standby roll comprises fixing both ends of a paper tube constituting a central axis of the standby roll to mechanical chucks, respectively, that are axially movably installed on the turret unwinder; and
the correcting comprises moving the mechanical chuck in the axial direction while operating a servomotor connected to the mechanical chuck based on the information about the position.

11. The sheet supply method of claim 9, wherein the detecting comprises detecting one of both axial ends of the standby roll by photographing it with a vision sensor.

12. The sheet supply method of claim 9, further comprising:
continuously detecting an edge of a sheet being unwound from the working roll after the standby roll has been switched to a position of the working roll; and
correcting the position of the working roll based on a deviation between a position of an edge at a preceding measurement point and a position of an edge at a subsequent measurement point among edges detected in the detecting the edge of the sheet.

13. The sheet supply method of claim 12, wherein the correcting a position of the working roll further comprises adjusting an unwinding angle of the sheet of the standby roll while moving the standby roll in an axial direction by controlling an operation of an edge position controller (EPC) that axially supports a bottom of the turret unwinder.
